(19) United States
(12) Patent Application Publication
(10) Pub. No.: US 2010/0032857 A1
(43) Pub. Date: Feb. 11, 2010

(54) Ceramic components, coated structures and methods for making same

(75) Inventors: Alain Izadnegahdar, Orange, OH (US); Yeshwanth Narendar, Westford, MA (US)

Correspondence Address: LARSON NEWMAN & ABEL, LLP, 5914 WEST COURTYARD DRIVE, SUITE 200, AUSTIN, TX, 78730, US

(73) Assignee: SAINT-GOBAIN CERAMICS & PLASTICS, INC., Worcester, MA (US)

(21) Appl. No.: 11/068,520

(22) Filed: Feb. 28, 2005

(51) Int. Cl. C23C 16/01; C23C 16/32; C04B 35/565

(52) U.S. Cl. 264/81; 427/249.15

(57) ABSTRACT

Methods of forming ceramic components are disclosed. One method calls for chemical vapor depositing a ceramic material over a substrate having first and second opposite surfaces to define a coated structure, the ceramic material forming a layer overlying both the first and second opposite surfaces. The layer and the substrate have a difference in thermal expansion coefficients of at least 0.5 ppm/K. The substrate is removed, leaving behind the layer. Ceramic components and coated structures are also disclosed.

### FEDERAL RIGHTS

This technical developments relative to this invention were partially supported by Government under contract No. DMI-0321616 awarded by National Science Foundation (NSF). The United States government may have certain rights in the invention.

### BACKGROUND

1. Field of the Disclosure

The present invention is generally drawn to coated ceramic structures, ceramic components, and methods of forming same.

2. Description of the Related Art

Ceramics are robust materials useful in various applications, including as superconductors, semiconductors, abrasives, electrical and thermal insulators, coatings, optical components, and structural components. Various oxide and non-oxide ceramic structural components have been utilized in particularly demanding applications in the context of high temperature environments, highly corrosive environments, and high wear environments. In such environments, it has been shown that silicon carbide (SiC) is a corrosion resistant and thermally stable material. However, processing of materials such as silicon carbide into useable components remains expensive and challenging, due in part to the hardness of the material and high temperature processing required for fabrication. For example, robust, high temperature ceramic materials such as silicon carbide may be fabricated through various processing pathways, including reaction bonding, sintering, hot pressing, and hot isostatic pressing. However, these techniques generally have limitations in the final density of the as-manufactured component, are expensive, waste material, and/or are limited to simple shapes and contours. Utilization of one of the foregoing processing pathways to form a complex shaped or micro-contoured ceramic component oftentimes requires post-processing or post-densification material removal procedures, such as machining or lithography/etch processing.

Various techniques for micro-machining a silicon blank are described in U.S. Pat. No. 6,171,972, dated Jan. 9, 2001. Here, MEMS (micro-electro mechanical systems) components are fabricated through various material removal processes such as deep reactive ion etching to form a silicon micro-machined device. However, the final components are limited in application due to material limitations associated with silicon.

In light of the foregoing, the industry has looked to alternative techniques for forming high performance ceramic components, such as high temperature, corrosion resistant, and mechanically robust ceramic components having fine features, such as MEMS components. One approach is detailed in U.S. Pat. No. 6,136,243, which describes a process in which conventional, low-cost silicon wafer processing is utilized to pattern a silicon semiconductor wafer followed by deposition of silicon carbide by CVD (chemical vapor deposition). However, in practice, the techniques disclosed in U.S. Pat. No. 6,136,243 have marked limitations, and a need continues to exist in the art for improved ceramic component processing, particularly processing for ceramic micro-components such as MEMS components.

### SUMMARY

According to one aspect, the present disclosure calls for a method of forming a ceramic component, including chemical vapor depositing a ceramic material over substrate to form a layer thereon, and removing the substrate leaving behind the layer. The substrate has first and second opposite surfaces, and the layer overlies the first and second opposite surfaces. Further, the layer and a substrate have a difference in thermal expansion coefficients of at least 0.5 ppm/K.

According to another embodiment, a method of forming a ceramic component is provided, including depositing a ceramic material over a substrate to form a layer thereon, and removing the substrate leaving behind the layer. Deposition of the ceramic material is carried out by (i) chemical vapor depositing a first film comprised of the ceramic material, (ii) cooling the substrate and the first film and (iii) chemical vapor depositing a second film comprised of a ceramic material to overlie the first film. The layer includes the first and second films, and the layer and the substrate have a difference in thermal expansion coefficients of at least 0.5 ppm/K.

According to another embodiment, a method of forming a ceramic component includes chemical vapor depositing a ceramic material over a substrate to define a coated structure, and removing the substrate leaving behind the deposited ceramic material intact and substantially free of cracks. The ceramic material forms a layer overlying the substrate having a thickness not less than 30 microns, and the layer and the substrate have a difference in thermal expansion coefficients of at least 0.5 ppm/K.

According to another embodiment of the present invention, a method of forming a plurality of ceramic components is provided. Here, a layer comprised of ceramic material is chemical vapor deposited over a patterned surface of a substrate to form a coated structure. The substrate is removed, and the remaining layer is processed into a plurality of ceramic components.

According to another embodiment, a method for forming a crack-free ceramic layer calls for chemical vapor depositing a ceramic material over a substrate to form a coated structure, the ceramic material forming a layer overlying the substrate, and cooling the coated structure, which remains crack-free upon completion of cooling.

According to yet another embodiment, a method for forming a crack-free ceramic layer is provided, including chemical vapor depositing a ceramic material over a substrate to define a coated structure, and cooling a coated structure, the ceramic material forming a ceramic layer remaining crack-free upon completion of cooling. Here, depositing is carried out such that the layer extends so as to overlie both first and second opposite surfaces of the substrate, and the layer and the substrate have a difference in thermal expansion coefficients of at least 0.5 ppm/K.

Still further, a method of forming a crack-free ceramic layer is provided, including depositing a ceramic material over a substrate to form a layer overlying the substrate and defining a coated structure, and cooling the coated structure, the ceramic layer being crack-free upon completion of cooling. Depositing includes chemical vapor depositing a first film comprised of the ceramic material, (ii) cooling the substrate and first film, and (iii) chemical vapor depositing a second film comprised of the ceramic material to overlie to the first film. The layer comprises the first and second films, and the layer and the substrate have a difference in thermal expansion coefficients of at least 0.5 ppm/K.

The first and second chemical vapor deposition steps may be carried out at a temperature not less than 800° C., at first and second deposition rates r₁ and r₂ respectively, to form first and second films having thicknesses t₁ and t₂, respectively. According to one feature, t₂>2 t₁, r₂>2 r₁, and the layer may have a thickness not less than about 30 microns.

Various coated structures are also provided including a patterned silicon wafer substrate and a silicon carbide layer overlying the patterned silicon substrate. In one variation the silicon carbide layer may have a density not less than about 98% of theoretical density and a thickness not less than 40 microns, the coated structure being crack-free at room temperature. According to another variation, the silicon carbide layer is a CVD silicon carbide layer, having a thickness not less than about 30 microns, the coated structure being crack-free at room temperature. According to yet another variation, a coated structure is provided including a silicon wafer substrate having first and second opposite surfaces and a pattern extending along at least one of the opposite surfaces. A silicon carbide layer overlies both the first and second opposite surfaces of the silicon wafer substrate.

### BRIEF DESCRIPTION OF THE DRAWINGS

The present disclosure may be better understood, and its numerous features and advantages made apparent to those skilled in the art by referencing the accompanying drawings.

FIG. 1 illustrates a substrate prior to patterning.

FIG. 2 illustrates patterning of the substrate shown in FIG. 1.

FIGS. 3A, 3B and 3C illustrate various views of a substrate after completion of patterning.

FIGS. 4A and 4B illustrate views of ceramic material deposition after patterning.

FIGS. 5 and 6 illustrate alternative embodiments of coated structures, including substrates having been subjected to dual-sided deposition.

FIG. 7 illustrates a substrate after a machining operation.

FIG. 8 represents an exploded, partial view of a plurality of ceramic components following substrate removal, prior to separating individual ceramic components.

FIG. 9 illustrates an SEM polished cross section of a coated structure after cooling according to one experimental procedure.

FIG. 10 illustrates an SEM partial surface image of a substrate coated with a crack-free CVD-SiC layer according to another experimental procedure.

FIG. 11 illustrates a low magnification SEM image of a polished cross section according to another experimental procedure.

The use of the same reference symbols in different drawings indicates similar or identical items.

### DESCRIPTION OF THE PREFERRED EMBODIMENT(S)

According to particular embodiments hereinbelow, ceramic components and various methods for forming same, coated structures (including particular layers thereof) and various methods for forming same, are described. In reference to the drawings, processing of one embodiment begins with provision of a substrate 100 shown in FIG. 1. The substrate 100 has first and second opposite surfaces 102 and 104, respectively. It is noted that the structures illustrated in the drawings are not necessarily drawn to scale, and in the case of substrate 100, the substrate may have a significantly minimized thickness relative to the dimensions of the first and second opposite surfaces. Oftentimes, substrate 100 is in the form of a wafer, having a relatively minimized thickness relative to diameter. As used herein, ‘wafer’ generally corresponds to a planar substrate that has a maximum geometrical dimension (e.g., diameter) that is at least fifty times, such as at least one hundred times, the thickness of the wafer. According to one embodiment, the substrate is in the form of a substrate wafer, which are readily available commercially in 4, 6, 8 and 12 inch or even larger diameters.

Further, as noted above, the substrate may be formed principally of silicon, which may be polycrystalline silicon or monocrystalline silicon. Due to availability, monocrystalline silicon wafers are typically utilized. In this regard, silicon substrates may be preferentially used according to embodiments herein, as patterning technology for silicon substrates is well developed, readily available, and inexpensive to implement.

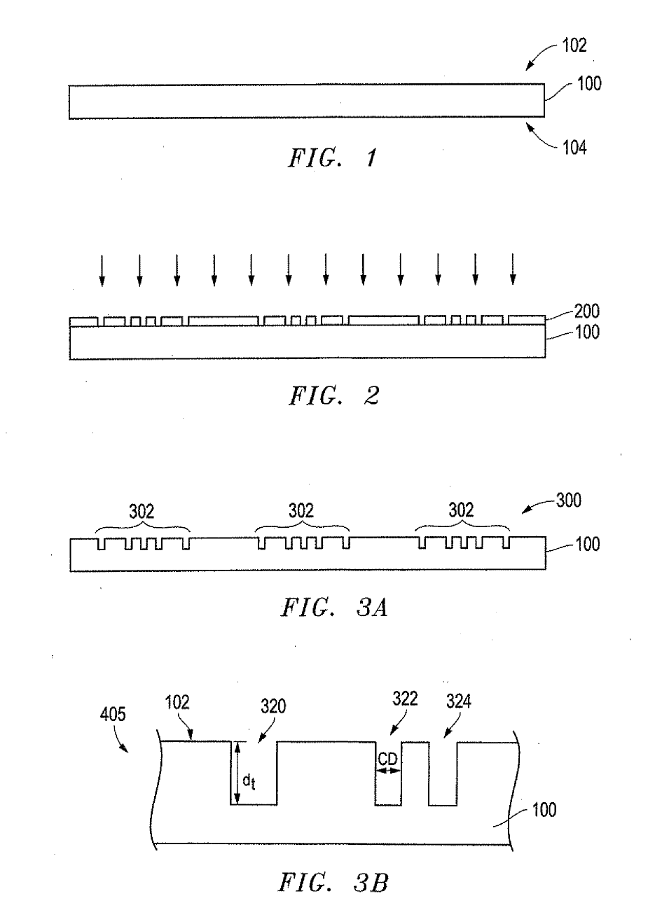

Active processing of the substrate continues in FIG. 2, with deposition of a mask layer 200. The mask layer 200 may be formed through semiconductor processing techniques, such as by deposition of a photoresist material, followed by lithographic exposure and subsequent development, to define a precise pattern that exposes selective underlying portions of the substrate 100. Process details for formation of the mask layer, such as via a photoresist route, are well understood in the art of semiconductor wafer processing. The arrows represented in FIG. 2 represent exposure of the substrate to an etching environment, whereby those portions exposed by or through the mask layer 200 are etched, such that material is selectively removed. Various chemistries are available for silicon wafer substrates, such as reactive ion etching, plasma etching or wet etching in a strong base such as KOH or tetra-methyl ammonium hydroxide (TMAH) or others.

FIG. 3A illustrates substrate 100 after completion of etching and removal of mask layer 200. As illustrated, the pattern of the mask layer 200 is transferred into the substrate 100 as pattern 300. In the particular embodiment shown in FIG. 3A, pattern 300 has a plurality of microfeature groups 302 repeated along the length of the cross-section illustrated in FIG. 3A.

Turning to FIG. 3B, a partial, exploded view of a portion of one microfeature group 302 is illustrated. The group includes several trenches 320, 322 and 324. Trench 320 has a maximum depth dₜ typically on the order of at least several microns. More typically, the trenches have a maximum depth not less than about 30 microns, such as not less than about 50 or 75 microns. Other embodiments have fairly deep trenches, having a maximum trench depth on the order of not less than about 100 microns or even 150 microns. FIG. 3B also illustrates the critical dimension (CD) of the substrate. Typically, critical dimension (CD) in the context of semiconductor manufacturing refers to the dimension of the smallest geometrical features (for example, width of interconnect line, contacts, trenches, etc.) that can be formed during semiconductor device/circuit manufacturing using a given technology. Here, critical dimension (CD) is defined as the smallest geometrical feature of the pattern extending along the substrate. According to the embodiment shown in FIG. 3B, this geometrical feature is the width of trench 322. According to various embodiments, the critical dimension (CD) of a patterned substrate may be not greater than about 1000 microns such as not greater than 500 microns. Other embodiments have even finer CD, such as not greater than 200 microns, not greater than about 100 microns, or even not greater than about 50 microns. Various embodiments may have an even finer structure, having a CD not greater than 10 microns.

Turning to FIG. 3C, a plan view of the substrate after completion of patterning is illustrated. Here, substrate 100 has a generally circular contour having a characteristic flat edge or straight edge as is well understood in the art of semiconductor processing. The substrate 100 in the form of a patterned wafer includes an array 310 of microfeature groups 302. In plan view, the microfeature groups 302 are generally formed in a two dimensional array as illustrated.

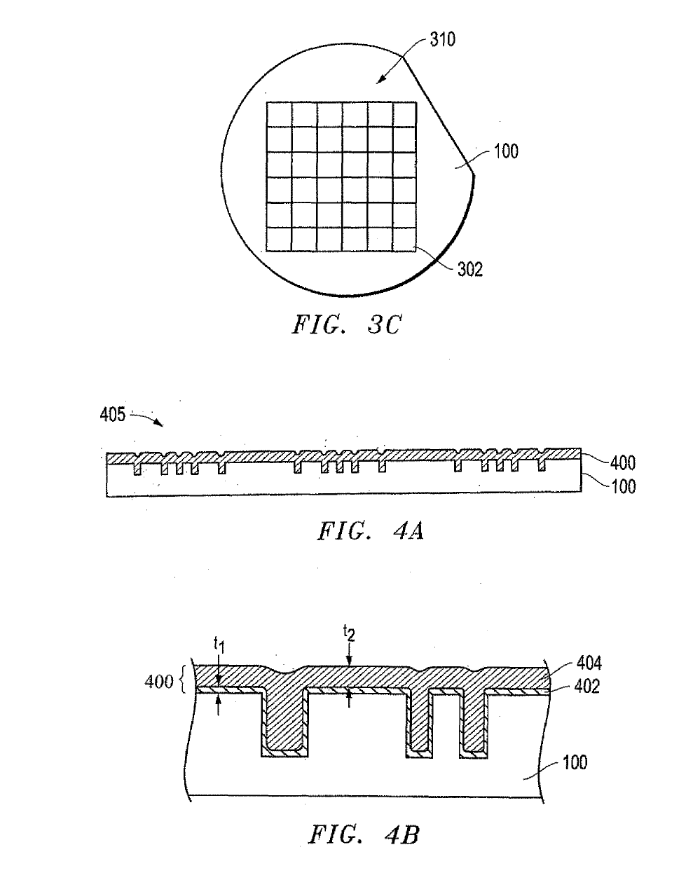

Processing then typically continues with the formation of a coated structure 405, illustrated in FIG. 4A. Here, the substrate 100 after patterning is then subjected to a deposition process in which a ceramic material is deposited to form layer 400. According to a particular characteristic, the layer 400 may have a mismatch in thermal expansion coefficients with the underlying substrate 100. Typically, this mismatch is at least about 0.5 ppm/K, oftentimes not less than 0.75 ppm/K, or even not less than about 1.0 ppm/K, or not less than about 1.2 ppm/K. Generally, these values are average values within a temperature range of interest, such as 300-1300° C. In one embodiment, the substrate comprises mainly silicon, such as in the case of polycrystalline or monocrystalline wafer substrates, and the deposited layer 400 is formed of silicon carbide. In this case, the CTE mismatch between substrate 100 and layer 400 is about 1.0 ppm/K (average CTE of SiC is about 5.2 ppm/K between 300-1300° C., while the average CTE of Silicon is about 4.2 ppm/K between 300-1300° C.). In this regard, attention is drawn to FIG. 12 plotting CTE of an Si wafer and CTE of CVD-SiC. The data reported in FIG. 12 were generated using controlled measurement equipment and characterization analysis, to ensure accurate evaluation of the CTEs of the materials and difference therebetween. In this regard, it was found that the technical literature oftentimes reports CTE values of 2.5 ppm/K and 4.5 ppm/K; however, as confirmed by FIG. 12, those values are for disparate temperature ranges, not the same temperatures range such as 300-1300° C. as reported above. Note that the noise in the early measurements between 300-400° C. are due to instrument issues.

FIG. 12 also plots thermal strain, where thermal strain is calculated from difference in average CTE from room temperature to the temperature at any point on the X-axis; viz. thermal strain from coating an Si wafer with CVD-SiC at different temperatures from 300-1300 C and cooling the coated wafer to room temperature.

While various deposition techniques may be utilized for the formation of layer 400, most typically layer 400 is deposited by a chemical vapor deposition (CVD) process. In the particular case of silicon carbide, silicon carbide may be deposited in the form of a conformal layer by utilizing a gaseous precursor such as MTS and H₂ in an inert carrier gas such as Ar. Generally, deposition is carried out to form a relatively thick layer, such as a layer having a thickness not less than 30 microns, such as not less than about 50 microns, 75 microns, or even not less than about 100 microns. Additional embodiments have even greater thicknesses, such as not less than about 150 microns and even greater.

According to embodiments herein, the deposited ceramic layer has a high density, generally not less than 98% of theoretical density, even more typically not less than 99% of theoretical density. Indeed, chemical vapor deposition may be carried out to achieve a minimum of 99.5% dense, such as 99.9% dense layers, with working examples achieving 100% dense layers. In addition, it is noted that the deposited ceramic layer, such as CVD-SiC is generally polycrystalline, and grain orientation can be varied from highly aligned to a random texture with control of the deposition conditions. Crystal domain alignment in the layer may be achieved for applications requiring alignment, through ion-beam assisted deposition and use of crystal-textured substrates, if needed.

Turning to further processing details with respect to layer 400, attention is drawn to FIG. 4B, illustrating a more detailed view. Here, as shown, layer 400 includes a first layer 402 and a second layer 404. The first and second layers are generally deposited by chemical vapor deposition, the first layer being comparatively thin with respect to the second layer. To give a better sense of relative thicknesses, FIG. 4B shows the first film 402 having a thickness t₁, and the second film having a thickness t₂. Generally, t₂ is greater than 2t₁, and in other embodiments, t₂ is greater than 5t₁, and in other embodiments t₂ is greater than 10t₁. Oftentimes, t₁ is not greater than 20 microns, such as not greater than 10 microns, or even not greater than 5 microns. Qualitatively, t₁ is generally formed to be relatively thin and conformal, followed by deposition of the relatively thick film having thickness t₂. According to a particular process feature, after deposition of t₁ by a high temperature process such as by chemical vapor deposition, the thus coated structure formed of the substrate and the first film 402 is cooled. Generally, cooling is carried out such that the temperature of the coated structure is reduced several hundred ° C., from the CVD processing temperature for forming first film 402. The first film 402, as deposited by chemical vapor deposition, is generally carried out at a temperature not less than about 800° C., generally not less than about 900° C., and oftentimes not less than about 1000° C. Actual processing temperatures oftentimes lie within a range of about 1100° C. to 1300° C. Typically, the substrate and the first film prior to deposition of the second film 404, is cooled to a temperature not greater than 400° C., such as not greater than 1000° C., and oftentimes to room temperature.

According to one process parameter, the first film 402 is deposited at a deposition rate r₁, and a second film 404 is deposited at a deposition rate r₂. r₂ is generally greater than 2r₁, such as greater than 3r₁. In this way, fine thickness control may be carried out with respect to deposition of first film 402, to ensure formation of a uniform, conformal thin film, followed by higher rate deposition of film 404 to achieve adequate throughput during processing. In addition, the controlled growth of the first film utilizing a comparatively slow growth process may assist in alleviating residual stresses in the film, discussed below. According to one development, the deposition of the first, second and additional films may be carried out in the same deposition apparatus, which is cost-effective. In contrast, conventional processes oftentimes require switching between deposition tools or apparatuses, requiring additional and expensive equipment toolsets.

While only first and second films 402 and 404 are illustrated in FIG. 4B, it is understood that additional films may be present as well, or second film 404 may be deposited in the form of several discrete films. As may be desirable, each succeeding film may be deposited at an increasing deposition rate and/or thickness. However, whether two, three, four, or five or more films are present, generally the first film 402 is conformal, is deposited to be in direct contact with substrate 100, and has a relatively low thickness as noted above.

Turning to FIG. 5, an alternative embodiment is illustrated. Here, coated structure 505 includes substrate 100, but with a conformal layer 500 of ceramic material extending to cover both the first and second opposite major surfaces 102 and 104. The coated structure 505, representing a dual-sided deposition process, may be carried out by ensuring the backside or second opposite surface 104 of the substrate 100 is exposed to the reactants during chemical vapor deposition. In practice, this may be achieved by physically hanging the substrate in the deposition chamber of the CVD apparatus. As discussed in more detail below, this approach, executing dual-sided deposition, may be particularly desirable in certain applications. The substrate may be hung by placing a hole in the substrate such that a hook or other mechanism can be engaged to support the weight of the substrate during deposition.

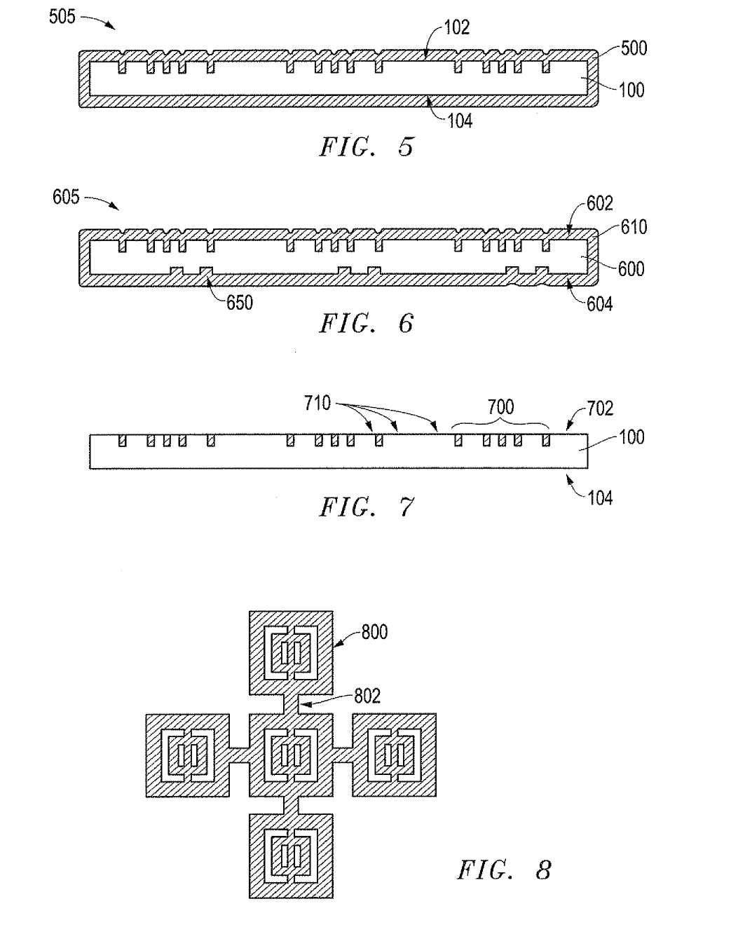

FIG. 6 illustrates a modification of the embodiment shown in FIG. 5. Here, coated structure 605 includes a substrate 600 having a backside pattern, and conformal layer 610. Particularly, substrate 600 includes a second pattern 650 extending along the second opposite surface 604. The backside pattern may function to further equalize contraction of the opposite major surfaces of the substrate, further attenuating residual stress and/or deformation. In addition, the backside pattern may be utilized to double the throughput of the process, by taking advantage of both opposite major surfaces for ceramic component fabrication. In this context, the backside pattern may be similar to or even identical to the pattern extending over the opposite surface. Even further, the opposing patterns may intersect each other to form complex-shaped ceramic components (subsequent to substrate removal, mentioned below).

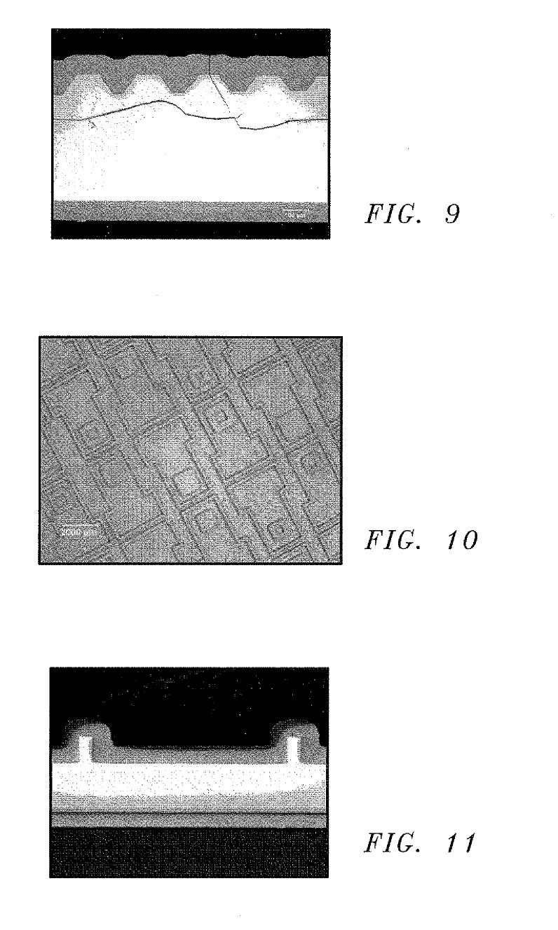

FIG. 7 illustrates a next processing step in which the coated structure 405 is machined to expose processed surface 702. Here, the coated structure is machined to remove deposited ceramic material and to expose portions 710 of the first opposite surface, leaving behind the pattern filled with ceramic material. While the processed surface 702 may generally correspond to the first opposite surface 102, oftentimes machining, such as by chemical mechanical planarization (CMP), may drive below the depth of the original first opposite surface 102. As should be clear, each microfeature group (see microfeature group 302 in FIG. 3a) of the substrate is filled with ceramic material, defining a complementary microfeature group 700.

Processing continues with removal of the substrate 100. Typically the substrate is removed by processes such as etching utilizing a strong base such as potassium hydroxide (KOH) or tetra-methyl ammonium hydroxide (TMAH) to preferentially dissolve the substrate leaving behind the deposited ceramic material. Removal of the substrate leaves behind the deposited ceramic material in the form of a pattern comprised of the complementary microfeature groups 700.

Each complementary microfeature group corresponds to a ceramic component 800, illustrated more clearly in plan view FIG. 8. Here, a partial plan view of a plurality of individual ceramic components 800 is illustrated. In the particular embodiment illustrated, the individual ceramic components 800 are interconnected to each other by cleavage tabs 802 that represent a “bridge” between adjacent components. The cleavage tabs 802 are provided for handling ease such that upon removal of the substrate 100, the separation of individual ceramic components may be carried out under controlled conditions. Processing into individual components may be carried out by severing along the cleavage tabs, followed by light machining to remove any tab remnants, if desired for a given application. Alternatively, the patterns may be formed without provision for cleavage tabs, the ceramic components being separated from each other upon removal of the substrate. In such a case, processing into individual components and substrate removal are combined into a single step. Viewing the sequence of processing steps, it is clear that each microfeature group originally illustrated in FIG. 3A, defines a complementary microfeature group of deposited ceramic material after machining, and that each complementary microfeature group in turn defines an individual ceramic component.

While a particular structure of ceramic components 800 is illustrated in FIG. 8, it is to be understood that the actual structure or micro-architecture of the components may vary considerably based on application of the component. By way of example, application categories include MEMS (micro-electro mechanical systems) components or MMS (micro-machining systems) components, and within each of those categories, may take on varying micro-architectures.

According to several embodiments of the present invention described above, various structural and process features may be utilized to provide coated structures having a crack-free deposited ceramic layer, and consequently intact and crack-free components. For example, deposition may be carried out by a multi-step deposition process, preferably incorporating at least one intermediate cooling step such as discussed in connection with FIG. 4B. Generally a first thin film having a comparatively reduced thickness (relative to the entire thickness of the deposited ceramic layer) is first deposited and that coated structure is cooled, followed by reheating to carry out subsequent chemical vapor deposition step(s) to provide bulk film(s) to form the majority of the thickness of the deposited ceramic layer. Final cooling after all deposition steps have been completed results in an intact, crack-free coated structure that may be further processed as discussed hereinabove.

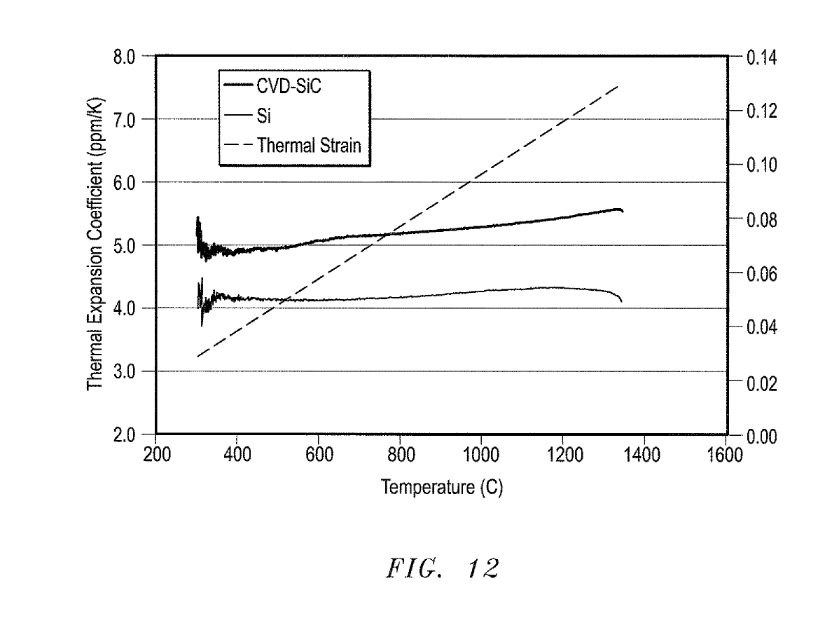

In contrast, according to the state of the art (mentioned in the Background), chemical vapor deposition is carried out to deposit a single thick film such as on the order of 100-500 microns. However, in practice, it has been found that crack-free structures cannot be formed by such a process. In the context of CVD-SiC on Si, the present inventors have recognized that the mismatch in thermal expansion coefficients between the substrate and the deposited layer generates excessive tensile stresses in the deposited layer causing catastrophic cracking. In this regard, attention is drawn to FIG. 9, a polished SEM cross section of a patterned 525 micron thick 4-inch silicon wafer carrying an 80 micron CVD-SiC coating. The CVD-SiC coating was deposited at 1125° C. in a single step process utilizing a reactant chemistry containing 0.9 percent MTS and 9 percent H₂ in Ar carrier gas. As illustrated, cracks propagated normal to the wafer in the CVD-SiC layer, a characteristic of CTE mismatch and induced tensile stress. Additional experimentation has also found that modified reactant recipes and processing temperatures were unsuccessful in depositing a crack-free CVD-SiC layers (further processing of the layers could not be continued to make intact ceramic components based on those deposited layers due to extensive cracking).

The art has also reported use of a single crystal SiC film prior to chemical vapor deposition of an overlying polycrystalline layer. While the prior art mentioned in the Background is silent on fabrication details of such a single crystal film, technical literature reports that such single crystal films are generally grown by either partially consuming the top surface of the silicon wafer by annealing in a hydrocarbon gas such as propane or acetylene or carbon rich carbosilane precursors such as hexamethydisilane or silacyclobutane. The reported single crystal films are limited to growth on polished planar silicon wafers with a defined crystallographic orientation along the (001) or (111) axis. That is, the growth of a single crystal SiC film on the silicon wafer requires the use of a flat and highly polished wafer with defined crystallography. As reported, surface defects in the form of polishing defects leads to changes in atom configuration along the surface that leads to grain misorientation during growth and prevents single crystal silicon carbide formation. In the context of a patterned substrate having a characteristic etch pattern along the surface, the patterned substrate is presented as a highly defect laden surface in the context of single crystal layer growth, and such a substrate suffers from even more severe defectivity issues as compared to polishing defects. Notably, a patterned surface causes notable grain misorientation during attempted growth of the single crystal layer. Thus, the formation of a single crystal SiC layer is generally not feasible on a patterned silicon wafer.

In addition, according to another feature, dual-sided chemical vapor deposition may be carried out. Dual sided deposition assists in minimizing bowing of the substrate upon cooling, and consequential substrate failure. That is, by providing a conformal layer surrounding the entirety of the substrate, most notably, the first and second opposite major surfaces, induced tensile stresses at the opposite major surfaces may be equalized and further enhance yield during production of ceramic components.

FIG. 10 illustrates a surface image of a 525 micron thick 4 inch silicon wafer carrying an 80 micron thick crack-free CVD-SiC layer deposited utilizing a two-step deposition process. More particularly, in the fabrication of the actual working embodiment, shown in FIG. 3, a thin, less than 5 micron, CVD-SiC layer was deposited slowly at a rate of less than 10 microns per hour. The CVD-SiC coating was deposited at 1125° C. using a dilute recipe of 0.5 percent MTS and 5 percent H₂ in Ar carrier gas. The thus coated substrate was cooled to room temperature; it was observed that the thin film and substrate were crack free. The coated substrate was placed into the deposition chamber and a second film, making up the bulk of the thickness of the deposited CVD-SiC layer (greater than 80 microns), was deposited utilizing similar process conditions at a higher deposition rate, namely 20 microns per hour. Without wishing to be tied to any particular theory, it is believed that the controlled growth of the first, thin CVD-SiC film may minimize tensile stresses during growth, and that cooling prior to deposition of the second film may be effective to form crystallographic dislocations in the substrate. It is believed that the induced dislocations in the underlying substrate, particularly at the interface with the first thin film, helps relieve thermal stresses from the CTE mismatch during cooling from the second deposition step and any subsequent deposition steps. As a result, the coated structure remains intact and crack free upon completion of cooling after final deposition.

FIG. 11 is a low magnification image of a polished cross-section of a 525 micron thick 4 inch patterned silicon wafer, carrying 125 microns of CVD-SiC coating deposited utilizing a three-step process. Here, deposition was carried out similarly as described above in connection with FIG. 10, but a third CVD-SiC film was deposited to increase thickness to 125 microns. As shown, the structure is crack-free, and the deposited ceramic material forms a conformal layer suitable for planarization or polishing.

The above-disclosed subject matter is to be construed as illustrative and not restrictive, and the appended claims are intended to cover all such modification, enhancements, and other embodiments that fall within the scope of the present invention. Thus, to the maximum extent allowed by law, the scope of the present invention is to be determined by the broadest permissible interpretation of the following claims and their equivalence and shall not be restricted or limited by the foregoing detailed description.

1. A method of forming a ceramic component, comprising:
providing a substrate first and second opposite major surfaces, wherein the first and second major surfaces are substantially parallel to each other and are separated by a thickness of the substrate;
forming a first pattern within the substrate, wherein the first pattern extends form the first opposite major surface;
chemical vapor depositing a ceramic material over a substrate to define a coated structure, the ceramic material forming a layer along each of the first and second opposite major surfaces and within the first pattern, the layer and the substrate having a difference in thermal expansion coefficients of at least 0.5 ppm/K; and
removing the substrate leaving behind the layer.

2. The method of claim 1, wherein the substrate is a wafer.

3. The method of claim 1, wherein the first pattern extends partly but not completely to the second opposite major surface of the substrate.

4. The method of claim 3, further comprising forming a second pattern extending along the second opposite major surface.

5. The method of claim 3, wherein the pattern comprises microfeatures.

6. The method of claim 5, wherein the microfeatures have a critical dimension not greater than about 500 microns.

7. The method of claim 6, wherein the critical dimension is not greater than about 200 microns.

8-13. (canceled)

14. The method of claim 1, wherein the difference in thermal expansion coefficients is not less than 0.75 ppm/K.

15-42. (canceled)

43. A method of forming a ceramic component, comprising:
depositing a polycrystalline ceramic material over a substrate to form a layer overlying the substrate, wherein depositing comprises (i) chemical vapor depositing a first film comprised of the polycrystalline ceramic material; (ii) cooling the substrate and the first film; and (iii) chemical vapor depositing a second film comprised of the polycrystalline ceramic material to overlie the first film, wherein the layer comprises the first and second films, and the layer and the substrate have a difference in thermal expansion coefficients of at least 0.5 ppm/K; and
removing the substrate leaving behind the layer.

44-46. (canceled)

47. The method of claim 45, wherein the pattern comprises microfeatures.

48. The method of claim 47, wherein the microfeatures have a critical dimension not greater than about 200 microns.

49-50. (canceled)

51. The method of claim 47, further comprising processing the deposited ceramic material to form a plurality of ceramic components.

52. The method of claim 51, wherein the microfeatures comprise a pattern of microfeature groups, each microfeature group defining a complementary microfeature group in the layer, each complementary microfeature group defining an individual ceramic component of the plurality of ceramic components.

53. The method of claim 51, wherein the plurality of ceramic components comprise a plurality of MEMS or MMS ceramic components.

54-57. (canceled)

58. The method of claim 43, wherein the polycrystalline ceramic material comprises SiC.

59. (canceled)

60. The method of claim 43, wherein the substrate comprises silicon.

61. The method of claim 60, wherein the substrate consists essentially of silicon.

62. (canceled)

63. The method of claim 43, wherein the layer has a thickness not less than 50 microns.

64-68. (canceled)

69. The method of claim 43, wherein the first film is deposited at a first deposition rate r₁ and the second film is deposited at a second deposition rate r₂, wherein r₂>2r₁.

70. (canceled)

71. The method of claim 43, wherein the first and second films are deposited at a temperature not less than 800° C. and not greater than 1300° C.

72. The method of claim 43, wherein cooling is carried out at a temperature not greater than 400° C.

73-74. (canceled)

75. The method of claim 43, wherein the film is deposited to a thickness t₁ and the second film is deposited to a thickness t₂, wherein t₂>2t₁.

76-115. (canceled)

116. A method of depositing a silicon carbide layer, comprising:
depositing a first polycrystalline silicon carbide film over a patterned silicon substrate by chemical vapor deposition at a temperature not less than 800° C. and at a rate r₁, the first polycrystalline silicon carbide film having a thickness t₁;
cooling the substrate and the first film to a temperature not greater than 400° C. after depositing the first silicon carbide film; and
depositing a second polycrystalline silicon carbide film over the first polycrystalline silicon carbide film by chemical vapor deposition at a temperature not less than 800° C. and at a rate r₂, the second polycrystalline silicon carbide film having a thickness t₂;
wherein t₂>2t₁, r₂>2r₁, and the silicon carbide layer is comprised of the first and second polycrystalline silicon carbide films, the silicon carbide layer having a thickness not less than 30 microns.

117-119. (canceled)

120. The method of claim 116, wherein each of depositing a first polycrystalline silicon carbide film and depositing a first polycrystalline silicon carbide film is performed at a temperature not greater than 1300° C.
